(19) United States
(12) Patent Application Publication
(10) Pub. No.: US 2013/0320481 A1
(43) Pub. Date: Dec. 5, 2013

(54) High Density Pyroelectric Thin Film Infrared Sensor Array and Method of Manufacture Thereof

(71) Applicant: Bridge Semiconductor Corporation, Pittsburgh, PA (US)

(72) Inventors: Howard Beratan, Forest Hills, PA (US); S.S.N. Bharadwaja, Monroeville, PA (US); Robert J. Morris,, Jr., Oakmont, PA (US)

(73) Assignee: Bridge Semiconductor Corporation, Pittsburgh, PA (US)

(21) Appl. No.: 13/900,001

(22) Filed: May 22, 2013

Related U.S. Application Data
(60) Provisional application No. 61/654,290, filed on Jun. 1, 2012.
(60) Provisional application No. 61/808,359, filed on Apr. 4, 2013.

(51) Int. Cl. H01L 37/00; H01L 27/16

(52) U.S. Cl. CPC H01L 37/00; H01L 27/16
USPC 257/467; 438/3

(57) ABSTRACT

A method of manufacturing a thermal sensor array comprises: (a) providing a first wafer comprising an integrated circuit; (b) providing a second wafer comprising a carrier substrate, a thermally sensitive layer, a first electrode and a second electrode; (c) applying a polymer to a bonding surface of at least one of the first wafer and the second wafer; (d) contacting the first wafer and the second wafer for a period of time and at a temperature and pressure sufficient to create a bond; (e) removing the carrier substrate; and (f) patterning and etching the thermally sensitive layer, the first electrode and the second electrode to create an array of pixels, wherein the first wafer and the second wafer are bonded without the need for fine alignment of the wafers.

### CROSS REFERENCE TO RELATED APPLICATIONS

This application claims the benefit of U.S. Provisional Application Nos. 61/654,290, filed Jun. 1, 2012, and 61/808,359, filed Apr. 4, 2013, both of which are incorporated herein by reference.

### BACKGROUND OF THE INVENTION

1. Field of the Invention

This invention relates to methods of making an infrared sensor array and particularly to methods of making a 25-micron pitch pixel array (as an example) using pyroelectric thin films.

2. Description of Related Art

One of the challenges of integrating pyroelectric thin films onto read-out integrated circuits (ROICs) is selection of the processing temperatures. In general, pyroelectric thin films made of lead titanate-based compositions require high temperature crystallizations at temperatures ranging from about 525° to 750° C. Such high temperature processing steps will preclude the monolithic integration of these thin film materials onto ROICs due to survivability issues at high temperatures (≧400° C.).

What is needed is a method of manufacturing infrared sensors that can accommodate the different processing temperatures of the various components.

### SUMMARY OF THE INVENTION

Disclosed herein is a hybrid monolithic integration method for preparing a pyroelectric thin film infrared sensor array without destroying the bottom read-out integrated circuit (ROIC). More specifically, disclosed is a method of manufacturing a thermal imaging sensor comprising: (a) providing a first wafer comprising an integrated circuit; (b) providing a second wafer comprising a carrier substrate, a thermally sensitive layer, a first electrode and a second electrode; (c) applying a polymer to a bonding surface of at least one of the first wafer and the second wafer; (d) contacting the first wafer and the second wafer for a period of time and at a temperature and pressure sufficient to create a bond; (e) removing the carrier substrate; and (f) patterning and etching the thermally sensitive layer, the first electrode and the second electrode to create an array of pixels; wherein the first wafer and the second wafer are bonded without the need for fine alignment of the wafers.

Also disclosed is a method of increasing the fill factor (i.e., the ratio of active pixel area to pixel pitch area) in an array of pixels in a thermal imaging system, the method comprising the steps of: (a) providing a wafer comprising an integrated circuit, a first sacrificial layer, a bottom electrode, a thermally sensitive layer, a top electrode and a second sacrificial layer on top of the top electrode; (b) depositing a thermally insulating electrically conductive layer on top of the sacrificial layer; (c) patterning and etching the thermally insulating electrically conductive layer into support arms that provide electrical connectivity from the first electrode to the integrated circuit and the second electrode to the integrated circuit; and (d) removing the first and second sacrificial layers, wherein the support arms are positioned above but separate from the top electrode of each pixel in the array of pixels.

Also disclosed is a pixel in a thermal imaging system, the pixel comprising an integrated circuit, a bottom electrode associated with a first arm, a thermally sensitive layer, a top electrode associated with a second arm, the first and second arms providing electrical connectivity for the bottom and top electrodes, respectively, to the integrated circuit, each first and second arm positioned above but separated from the top electrode on the pixel, on the side incident to incoming thermal radiation.

### BRIEF DESCRIPTION OF THE DRAWINGS

FIG. 1 illustrates a top perspective view of a pixel-sized portion of a first wafer comprising an ROIC;

FIG. 2 is a cross-section of the second wafer coupled to a carrier wafer prior to bonding to the first wafer;

FIG. 3 is a cross-section of the inverted first wafer bonded to the second wafer prior to removal of the carrier wafer;

FIG. 4 is a cross-section of the inverted first wafer bonded to the second wafer after removal of the carrier wafer;

FIG. 5 is a top perspective view of a pixel architecture of a sensor, wherein the pixel architecture includes the first and second wafers of FIG. 4 held in spaced relation by pixel arms after removal of the polymer layer in FIG. 4; and

FIGS. 6-9 are left, front, right, and backside views of the pixel architecture of FIG. 5.

### DETAILED DESCRIPTION OF THE INVENTION

As used herein in the specification and claims, including as used in the examples, and unless otherwise expressly specified, all numbers may be read as if prefaced by the word “about,” even if the term does not expressly appear. Also, any numerical range recited herein is intended to include all sub-ranges subsumed therein.

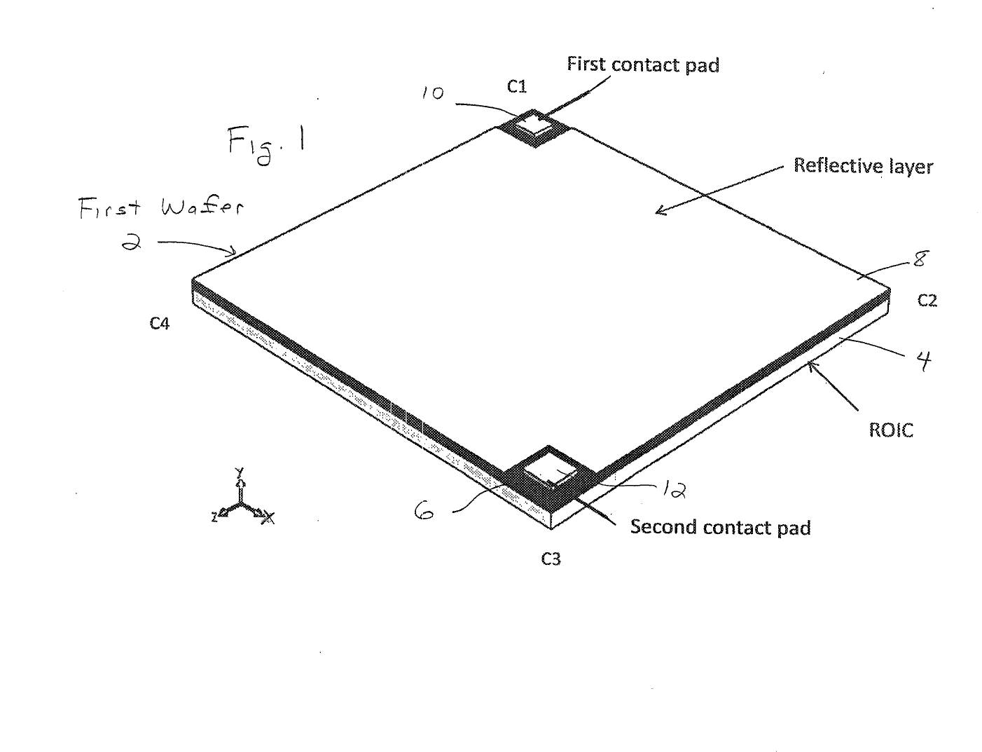

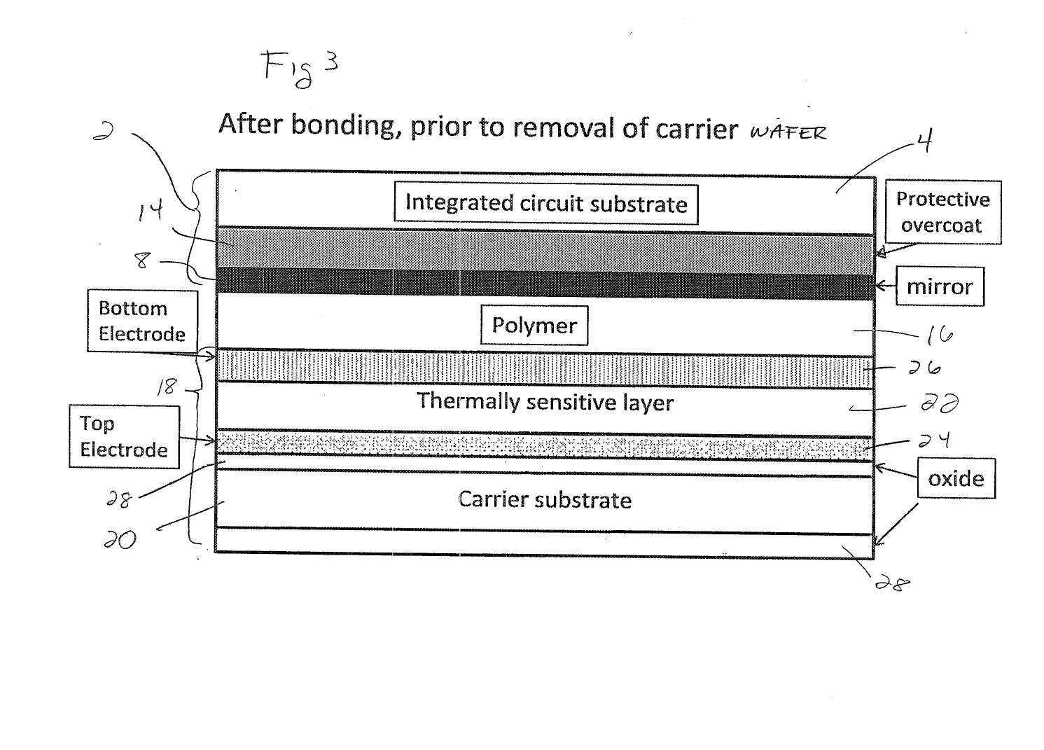

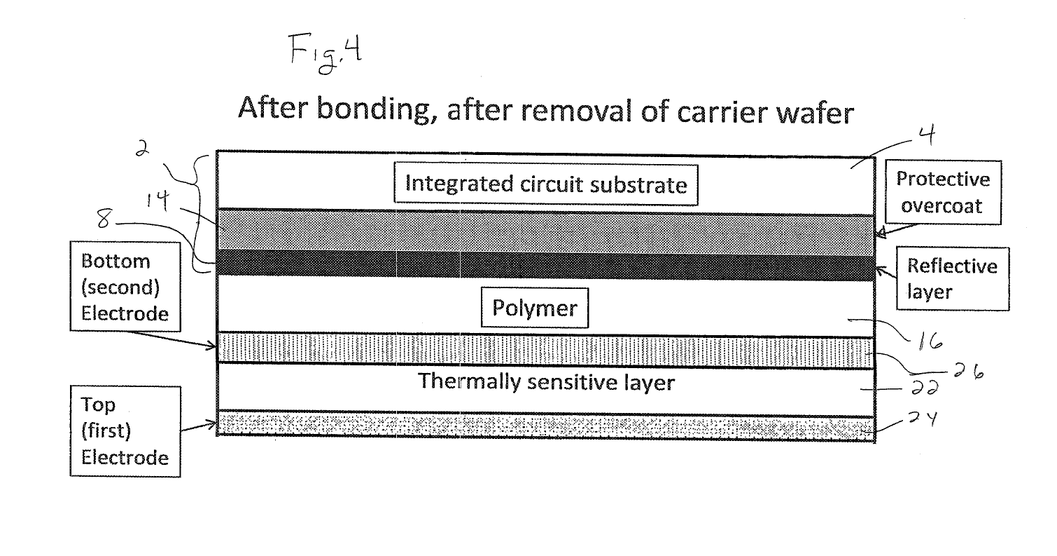

A pixel-sized portion of a first wafer 2 comprising a read-out integrated circuit (ROIC) 4 is schematically shown in FIG. 1. In some embodiments, ROIC 4 can be a CMOS integrated circuit. A top surface 6 of first wafer 2 is prepared with application of an electrically conductive reflective layer 8 atop of ROIC 4 that serves as an infrared reflector and which provides first and second contact pads 10 and 12 spaced from reflective layer 8 for making electrical connections to electronic circuitry (not shown) of ROIC 4. A protective overcoat 14 (not shown in FIG. 1 but shown in FIGS. 3-4), such as silicon nitride, is typically applied to ROIC 4 prior to application of reflective layer 8 to ROIC 4.

Suitable materials for use as the reflective layer 8 include, without limitation, metallics such as gold, chromium, TiW, TiAl, NiCr, Ti, Al, Cu, Ni, Pt, Pd, Ag, Ta, or combinations or alloys of any of these. Other electrically conductive materials can also be used. Reflective layer 8 is applied to ROIC 4 using physical vapor deposition methods at a thickness of 50 Å to 1,000 Å, depending on the material(s) used. Two or more metals or metal alloys can also be applied in separate layers, for example a layer of TiW followed by a layer of Al.

Following deposition of reflective layer 8, first wafer 2 is coated with a one- to two-micron thick blanket layer of polymer 16 (FIGS. 3-4), using chemical vapor deposition or spin-on methods. Suitable materials for polymer layer 16 include parylene-C, polyimides, benzocyclobutene (BCB), SU-8 type negative photoresists, or positive photoresists. A desirable polymer for polymer layer 16 is parylene-C.

Optionally, polymer layer 16 can be applied as a thinner blanket layer, on both first and second wafers 2 and 18 (FIG. 3). In this embodiment, for example, each of first and second wafers 2 and 18 are coated with an approximately one micron thick blanket layer of polymer 16. An appropriate adhesion promoter (not shown) can be coated on first and/or second wafers 2 and/or 18, if desired, prior to deposition of polymer layer 16, depending on the surface to which polymer layer 16 will be joined. First and second wafers 2 and 18 are then cleaned using solvents and/or plasma techniques.

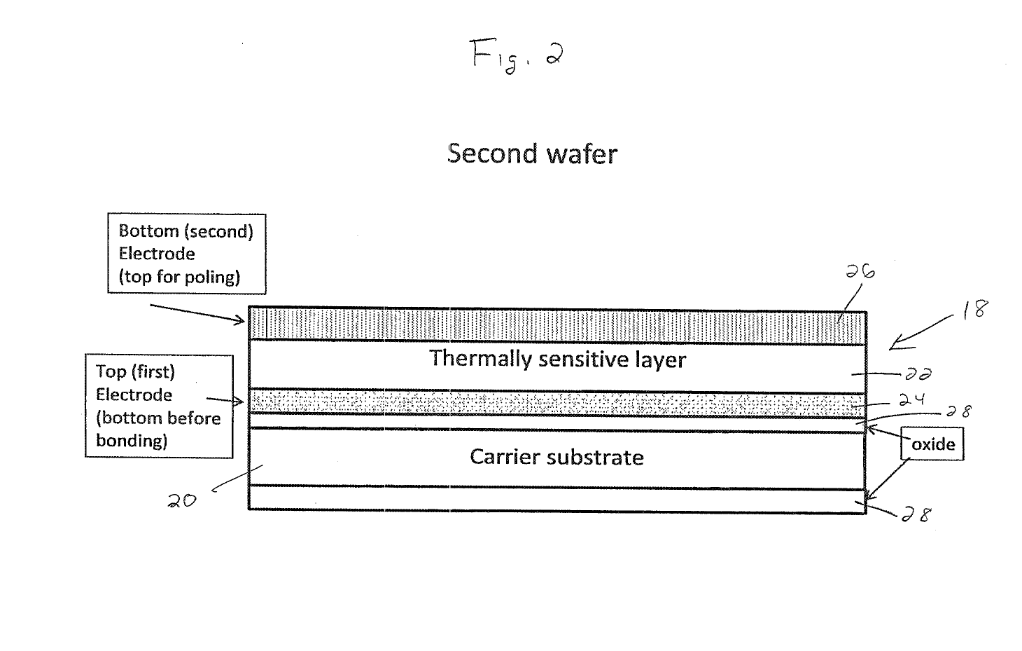

Second wafer 18, shown in cross-section in FIG. 2, comprises a carrier substrate 20, a thermally sensitive layer 22, a first, top electrode 24 and a second, bottom electrode 26, each deposited as described hereafter.

Carrier substrate 20 desirably is a single crystalline substrate such as silicon, magnesium oxide, calcium difluoride, sapphire, or other similar material known in the art. Optionally, carrier substrate 20 may be coated on either or both sides with an oxide or other protective layer 28 whose thickness ranges from 500 Å to 30,000 Å. Herein, ∈=Angstroms. Each protective layer 28 may be prepared by physical vapor deposition (PVD), thermal oxidation, organometallic chemical vapor deposition (OMCVD), chemical vapor deposition (CVD), or sol-gel processing. FIG. 2 illustrates an embodiment having two protective layers 28, in this case two oxide layers.

First electrode 24 is deposited on carrier substrate 20 (or on a protective layer 28, if present). First electrode 24 may be fabricated from any suitable and/or desirable electrically conductive material that is substantially transparent to thermal radiation. Suitable materials for first and second electrodes 24 and 26 include, without limitation, conductive oxides such as lanthanum nickelate (LaNi0₃ or LNO), indium-tin-oxide (ITO), Al-doped zinc oxide (AZO), Zn-doped indium oxide (IZO), LaSrCo0₃ (LSCO), LaSrMn0₃ (LSMO), (Sr₁₋ₓ,Baₓ)Ru0₃ (SRO), and iridium oxide (Ir0₂). When comprised of conductive oxides, the thickness of first and/or second electrode 24, 26 will be between 50 Å to 2000 Å, depending on the material used. In general, materials having a sheet resistance in the range of 100-2000 ohms/square are sufficiently transparent to allow passage of thermal radiation through the electrode 24 and/or 26 to thermally sensitive layer 22. For example, one electrode 24 or 26 may be very resistive, and the other electrode 26 or 24 may be moderately conductive, so in combination, they work to efficiently tune the pixel to absorb radiation.

High quality, low resistivity, [001]-textured conductive oxide thin films are desirable for first and second electrodes 24 and 26, and can be deposited onto thermally sensitive layer 22 via a sol-gel process or by PVD. Sol-gel starting materials are commercially available and are well known in the art.

After deposition, each electrode 24 and 26 is processed by low temperature pyrolysis (250°-450° C. for 30 seconds to 45 minutes) followed by high temperature crystallization (450°-750° C. for 30 seconds to 45 minutes) in air or oxygen at controlled dew-point. The final resistivity and/or sheet resistance of each electrode 24 and 26 can be adjusted by controlling thickness as well as final annealing conditions and stoichiometry (e.g., the La:Ni ratio, the indium:tin ratio, etc.).

During initial qualitative and quantitative electrical testing, first electrode 24 serves as a bottom electrode. After bonding, first electrode 24 is a top electrode in the pixel.

After deposition of first electrode 24, thermally sensitive layer 22 is deposited atop of first electrode 24. In some embodiments, thermally sensitive layer 22 may be deposited directly atop of and in contact with first electrode 24. In other embodiments, there may be an optional intervening layer that serves as a coupling layer.

Thermally sensitive layer 22 is desirably a pyroelectric material applied as a thin film. Suitable materials include, without limitation, lead-based titanates such as lead zirconate titanate (PZT), lead strontium titanate (PST), lanthanum doped lead zirconate titanate (PLZT), manganese doped lead zirconate titanate (PMZT), manganese doped lead lanthanum zirconate titanate (Mn:PLZT), 0.75Pb(Mg_{1/3}—Nb_{2/3})0₃-0.25PbTi0₃ (PMN-PT), Mg2+, Ca2+, Sr2+, Ba2+ doped lead zirconate titanate (e.g., Mg-PZT), lead tin titanate (PSnT) and its doped analogues, lead lanthanum titanate (PLT) and its doped analogues, and lead calcium titanate (PCT). Other suitable pyroelectric materials can also be used. Non-limiting examples of these include lithium-based materials such as lithium tantalate (LiTa0₃) and doped lithium tantalates; and barium-based materials such as barium strontium titanate (BST) and barium strontium calcium titanate. Doped versions of any of the above (in addition to those specifically listed), as well as analogues of any of the above, can also be used. Suitable dopants include, for example, La, Mn, V, W, Nb, Fe, Sr, Er, Ho, Ca, Ba, Sr, and Dy. Lead-based titanates are preferred, particularly Mn-doped lead zirconate titanate. Dopant concentration may range from 0.05% to 5%.

The pyroelectric thin film forming thermally sensitive layer 22 can be applied using sol-gel methods, followed by low temperature pyrolysis and high temperature crystallization in air or oxygen using a rapid thermal annealer. The final pyroelectric thin film forming thermally sensitive layer 22 will have perovskite structure and will be either untextured or highly textured films, desirably in (001) orientation. The final thickness of the pyroelectric thin film forming thermally sensitive layer 22 will be between 500 Å to 2 microns, more typically between about 0.3 to 0.5 microns.

When present, the optional coupling layer (not shown) between first electrode 24 and thermally sensitive layer 22 is comprised of a material having a dielectric permittivity between 5 and 150. In some embodiments, the dielectric permittivity is greater than about 25, for example, for a 50 Å thick coupling layer. Examples of material shaving this property include, without limitation, oxides, such as simple oxides including titanium dioxide (TiOₓ), zirconium oxide (ZrOₓ), and cerium oxide (CeOₓ). Other suitable materials include compound oxides such as strontium titanium oxide (SrTiOₓ) or cerium zirconium oxide (CeZrOₓ). The thickness of the coupling layer is typically in the range of about 50 Å to 1000 Å. The coupling layer may be grown by PVD, OMCVD, atomic layer deposition (ALD), or sol-gel processing.

After deposition of thermally sensitive layer 22, second electrode 26 material is deposited atop of thermally sensitive layer 22 one a side thereof opposite first electrode 24. Optionally, a coupling layer (not shown) as described above can be deposited between thermally sensitive layer 22 and second electrode 26.

Second electrode 26 is comprised of any suitable electrically conductive material that is substantially transparent to thermal radiation. In some embodiments, second electrode 26 is a thin film electrode comprised of one or more layers of thin film metals or metal alloys such as Ni Cr, TiAl, TiW, Au, Cr, Al, Cu, Ni, Pt, Pd, Ag, Cr, Ta, or combinations or alloys of any of these. In these embodiments, the electrode is between 50 Å and 150 nanometers in thickness, depending on the material used and the sheet resistance of the material, which is desirably in the range of 100-2000 ohms/square. In other embodiments, second electrode 26 can be any of the materials described above as suitable for the first electrode. Second electrode 26 can be the same material as first electrode 24, or it can be different.

The thin film metallic layer(s) forming second electrode 26 can be applied using known deposition methods such as RF sputtering in a low pressure Argon atmosphere (≦2.5 mTorr), optionally under substrate bias conditions (up to 30 watts).

Optionally, a ˜30-50 nm thick gold (Au) or aluminum (Al) metallic layer (not shown) can be deposited atop of second electrode 26 under substrate bias conditions to facilitate poling of thermally sensitive layer 22. Alternatively, this optional metallic layer can be a stack comprising a TiW layer in contact with second electrode 26 and with a layer of Au or Al on a side of the TiW layer opposite the second electrode 26. The metallic layer(s) forming second electrode 26 in combination with the optional metallic layer atop of the second electrode 26 serves as a top electrode for poling the pyroelectric film forming thermally sensitive layer 22 as well as for electrical, dielectric and pyroelectric testing. After poling of thermally sensitive layer 22 and testing, the optional metallic layer atop of second electrode 26 is removed. Once the pixels are fabricated, second electrode 26 serves as the bottom electrode (closest to the ROIC). FIGS. 3 and 4 illustrate the relative position of the various materials after bonding. Only one pixel is shown in the figures. However, it is to be understood that a number of pixels can be formed at the same time utilizing semiconductor or MEMs processing techniques known in the art.

In general, pyroelectric films require high field (˜2× the coercive field) poling to enhance the pyroelectric properties. Poling is the process of aligning the ferroelectric domains in a particular direction. A “domain” in a ferroelectric material refers to a region within the material in which the spontaneous/remnant polarization lies in a particular direction.

Desirably, in the methods of the invention, the poling process aligns the ferroelectric domains in an “out of plane” direction, i.e., in a direction not parallel to the plane of the pyroelectric film forming thermally sensitive layer 22.

To facilitate poling and testing, second, top electrode 26 is patterned into rectangular dice, e.g., without limitation, of about 9 mm×7 mm or 18 mm×14 mm in size, via conventional lithographic or shadow mask techniques. Second electrode 26 is exposed to a selective etch to facilitate poling, and to conduct electrical and pyroelectric characterization.

The patterned individual dice on second wafer 18 can then be poled either at room temperature or at high temperatures ranging from 100° C. to above the Curie temperature (Tc) of the pyroelectric film forming thermally sensitive layer 22. The poling process can also comprise one or more of the following steps:

1. Electric field, for poling, can be a direct current (DC) or milli to micro second range square/rectangular pulses below Tc.

2. Poling can be done by heating the pyroelectric film above Tc and applying DC or pulsed electric fields while cooling the wafer. This approach is known as the field cooling technique. Both approaches (1 and 2) can also be implemented, as an option, once the pixels are released using a common electrical port.

3. Poling can be done as described in step (1) and/or (2) above, but under compressing conditions of the pyroelectric film forming thermally sensitive layer 22.

After completion of poling, the second wafer 18 is aged at 150° C. for about 15 minutes, or at room temperature for 24 hours prior to testing the electrical and pyroelectric properties of the pyroelectric film forming thermally sensitive layer 22. After testing, the optional metallic layer (not shown) deposited atop of second electrode 26 can be removed using either conventional wet chemical or plasma etch techniques.

The poled dice on second wafer 18 are bonded to first wafer 2 comprising the readout circuit as described hereafter.

First wafer 2 and second wafer 18 are bonded together via polymer layer(s) 16 using standard wafer bonding techniques, at temperatures between 150-250° C. under uniaxial or hydrostatic load between about 15-250 psi at ambient pressure or in vacuum. The bonded first and second wafers 2, 18 is shown in FIGS. 3 and 4 (before and after removal of carrier substrate 20, respectively) and is referred to herein as “the bonded wafer.”

Successful bonding does not require fine alignment of first and second wafers 2, 18. As used herein, “fine” alignment refers to alignment at the 1-2 micron level. As used herein, “gross” alignment refers to alignment at the 1-2 millimeter level. Only gross alignment of the first and second wafers is necessary, because all patterning and etching steps (other than creating a die-sized poling electrode) are carried out after bonding, and thus there is no need to finely align specific features on the first and second wafers. Hence, only wafer level alignment is needed.

Carrier substrate 20 and, if present, protective (oxide) layers 28 of second wafer 18 are removed from the bonded wafer using known methods, such as grinding and chemical mechanical polishing (CMP), wet etch, plasma etch, chemical vapor etch, or deep reactive ion etching (DRIE), or any combination of these, to expose first electrode 24 as the top electrode of the pixel. FIG. 4 illustrates the bonded wafer after removal of carrier substrate 20.

Following removal of carrier substrate 20, the arrays of dice on the bonded wafer are patterned, using lithography (e.g., contact lithography or use of a stepper) (Level-1) followed by chemical or dry etch of first electrode 24, thermally sensitive layer 22, and second electrode 26, to create individual pixels. The final pitch of pixels on each die will be, for example, without limitation, 25 μm, where each pixel is a square of about 23×23 microns in size, separated by 2 microns from adjacent pixels.

Alternatively, poling of thermally sensitive layer 22 can occur after first wafer 2 and second wafer 18 are bonded together. In this alternative, first wafer 2 and second wafer 18 are bonded together after top electrode 26 has been patterned into regular dice via conventional lithographic or shadow mask techniques. Optionally, however, top electrode 26 can be patterned after first wafer 2 and second wafer 18 are bonded together. Thereafter, thermally sensitive layer 22 is poled after removal of carrier substrate 20 and, if present, protective layers 28.

Alternatively, thermally sensitive layer 22, with first and second electrodes 24 and 26, can be formed in a manner to have inherent polarization prior to bonding first wafer 2 and second wafer 18 together in the manner described above. Inherent polarization within pyroelectric/ferroelectric layers can be created via deposition schemes, such as vapor or chemical deposition, in the presence of electric fields in thermally sensitive layer 22 applied, for example, via first and second electrodes 24 and 26. This inherent polarization avoids the need to perform the poling process to align the ferroelectric domains in thermally sensitive layer 22 in the manner described above. Accordingly, the poling process described above can be eliminated when the thermally sensitive layer 22, having top and bottom electrodes 24 and 26, is provided with its ferroelectric domains aligned in the desired direction.

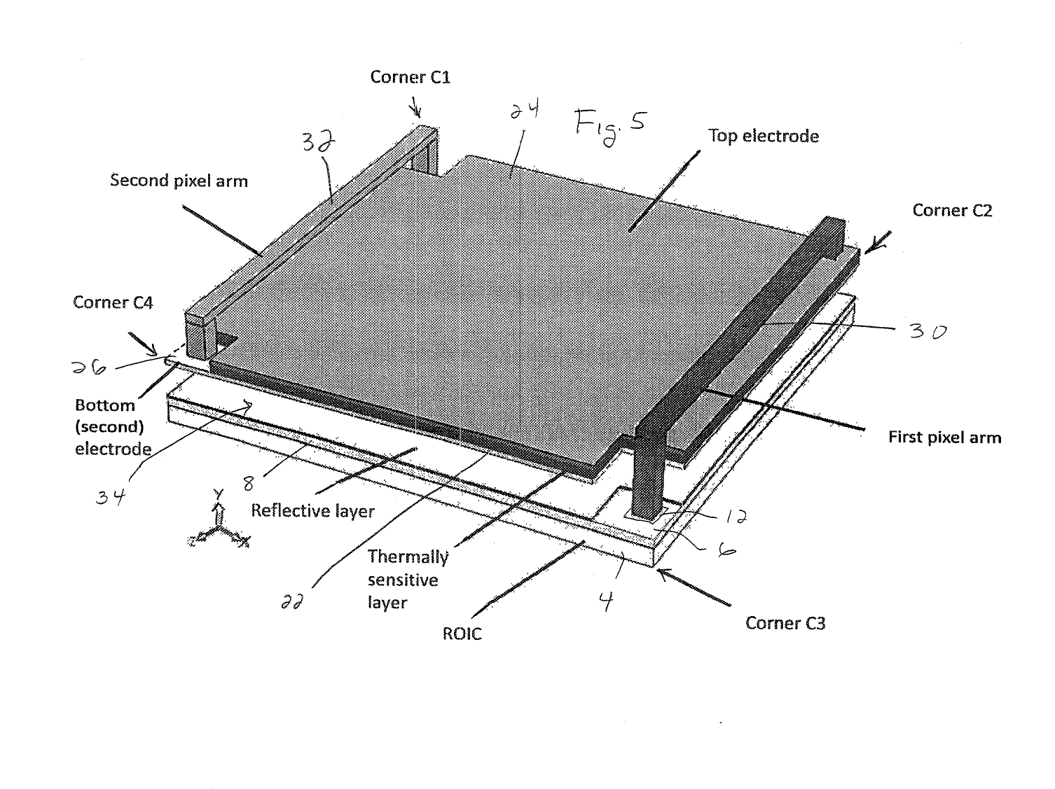

Referring to FIG. 5, each patterned pixel is then selectively etched to remove ˜4 or 5 microns square of first electrode 24 and thermally sensitive layer 22 at corners C1, C3, and C4 to expose second, bottom electrode 26 at these corners, using a combination of lithographic techniques and dry etching and/or wet chemical etching methods (Level-2). An additional lithographic pattern step is carried out to remove ˜4 or 5 microns square of second electrode 26 at corners C1 and C3 of each individual pixel (Level-3). Corner C2 is not etched.

Corners C1 and C3 are aligned with the contact pads 10 and 12 of first wafer 2 (corner C1 aligned to first contact pad 10 and corner C3 aligned to second contact pad 12) of an individual pixel circuit of ROIC 4. A dry etch technique is used to etch vias through the portions of polymer layer 16 in alignment between: (1) corner C1 and first contact pad 10 and (2) corner C3 and second contact pad 12, to enable electrical contacts to be formed between the pixel and the underlying individual pixel circuit of ROIC 4. In FIG. 5, polymer layer 16 is shown as having been removed in the manner described hereafter. An additional lithographic step may be used to remove any remaining metal layers around the vias, isolate them from the individual pixels. The size of via opened in polymer layer 16 is about 2 to 3 microns.

Once the vias between pixel corners C1 and C3 and the first and second contact pads 10 and 12, respectively, are formed, a photoresist layer (not shown) is deposited atop of the pixel, i.e., on a side of the pixel opposite ROIC 4. This photoresist is then patterned using lithographic patterning to expose corners C1, C2, C3 and C4 (all four corners of the pixel). A photoresist of ˜0.5 to 1 micron thick is employed in this step. This step exposes the vias patterned in polymer layer 16 at corners C1 and C3, and creates openings in the photoresist layer to enable pixel support arms (described hereafter) to contact bottom electrode 26 at corner C4, and top electrode 24 at corner C2.

The above-described patterning/etching steps are followed by deposition of a blanket layer having low electrical resistivity and high thermal resistance, such as a metal or metal alloy or composite or an oxide or nitride, atop of the patterned photoresist. The blanket layer is applied to a thickness of less than 0.2 microns, typically between about 100 Å to 1000 Å, to make electrical contact with first and second contact pads 10 and 12, a top surface of first electrode 24 and the portion of second electrode 26 exposed at corner C4. This blanket layer, applied after the first and second wafers have been patterned (after bonding), is referred to herein as “the arm layer.”

The arm layer is comprised of an electrically conductive and thermally isolating material. Suitable materials for the metal arm layer include, for example, TiAl, NiCr, TiW, TiN, TixMe₁₋ₓN and TaxMe₁₋ₓN (where Me=Ti, Zr, Hf, Nb, Ta, Mo, W). Multi-component materials can also be used, such as cermets, including chromium silicon monoxide or other cermets having a metal concentration by weight of about seventy percent to ninety percent and a corresponding ceramic concentration by weight of about thirty percent to ten percent. In addition to various cermets, the arms may be formed from a semiconductive material such as chromium oxides, silicon oxides, tantalum nitrides, tantalum oxides, tantalum oxidenitrides, polysilicons, and other metal oxides and metal nitrides. Conductive organic materials may also be used to form the arms.

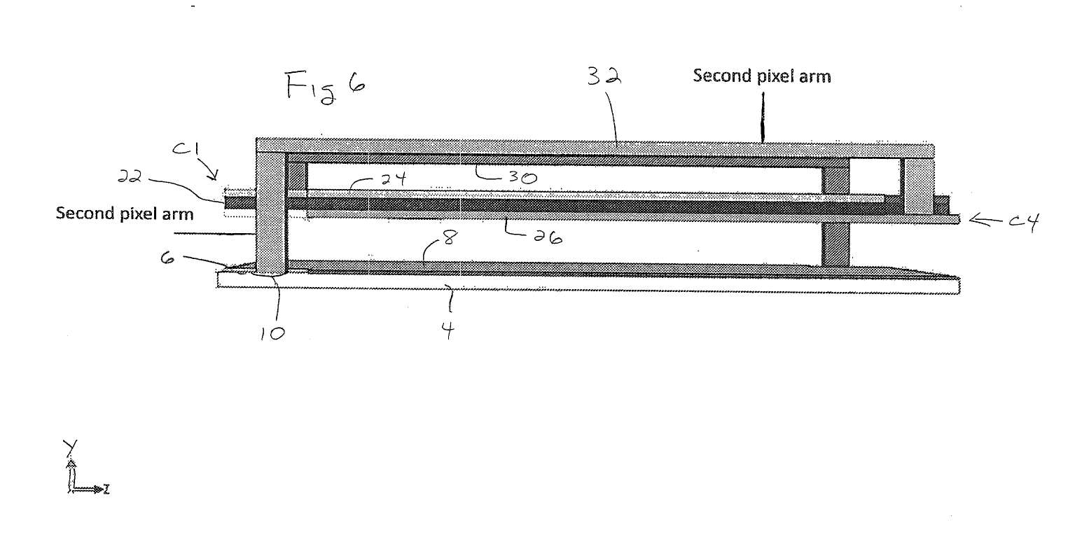

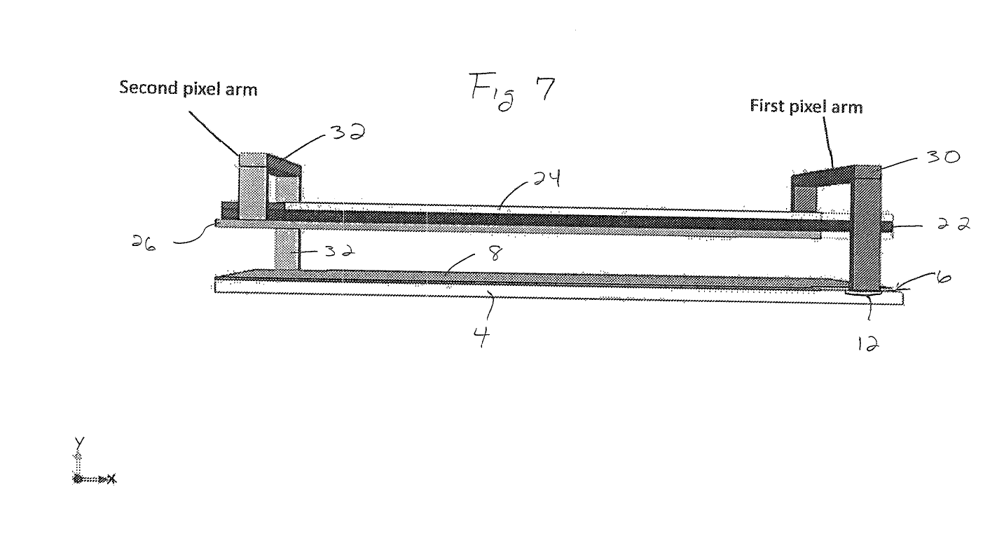

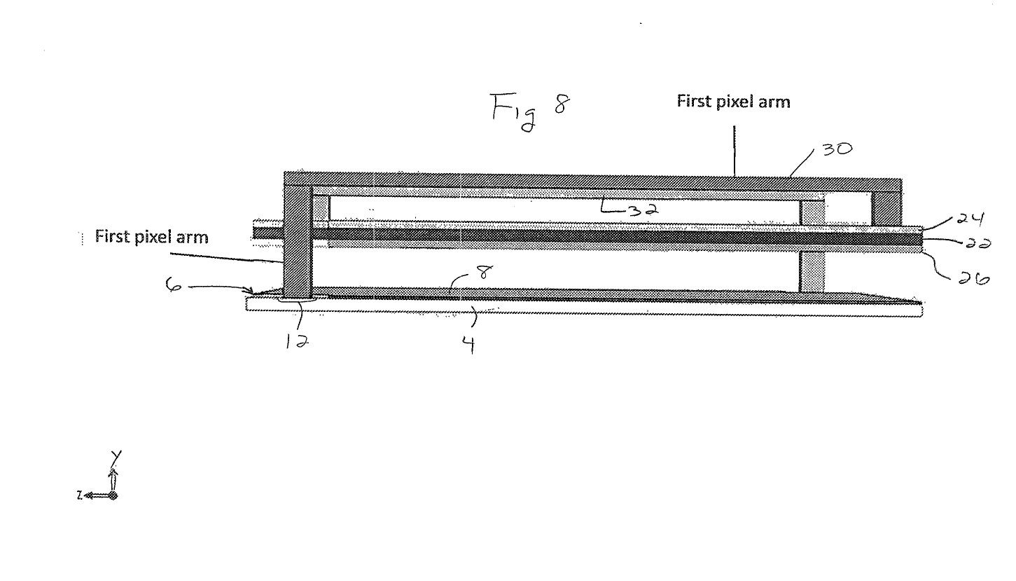

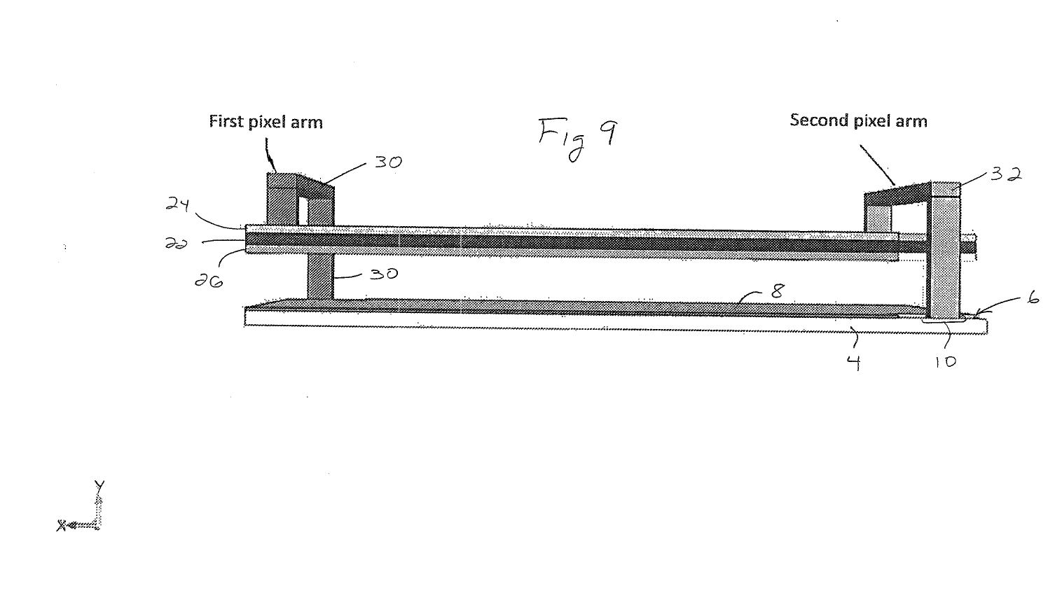

Referring to FIGS. 5-9, the arm layer is patterned to form first and second pixel support arms 30 and 32 positioned above first electrode 24, on side of the pixel incident to incoming thermal radiation. First and second pixel support arms 30 and 32 provide electrical connections between top and bottom electrodes 24 and 26 and second and first contact pads 12 and 10, respectively, of the underlying individual pixel circuit of ROIC 4. In addition, first and second pixel support arms 30 and 32 support the pixel (comprised of the portions of first electrode 24, thermally sensitive layer 22 and second electrode shown in FIG. 5) above the open space or gap 34 between the pixel and ROIC 4. If desired, for example for mechanical integrity purposes, pixel support arms 30 and 32 can be a conductor under an insulator, such as composite bilayers with metal as a lower layer and oxide/nitride as an upper layer.

Each pixel support arm 30 and 32 can optionally comprise two separate components, for example, a “post” portion of the arm that extends perpendicularly from ROIC 4 up to the pixel, and an “extension” portion of the arm that extends from the post, above the pixel, in a plane parallel to the pixel. The post and extension portions of the arm can be the same material, or they can be different. The post and extension portions of the aims can also have different dimensions, including different thicknesses.

Upon removal of the photo resist layer in the final processing steps (described below) pixel support arms 30 and 32 are separated from the top surface of the pixel as shown in FIG. 5. Positioning pixel support arms 30 and 32 in this manner provides a method of increasing the electrical fill-factor of pixels on an array without substantially hindering detection of the incoming infrared radiation, so long as the width of pixel support arms 30 and 32 is small compared to the wavelength of radiation being detected. The dimensions of pixel support aims 30 and 32 depend on the material used in making pixel support arms 30 and 32, e.g., for TiAl, dimensions of each pixel support arms 30 and 32 are about 0.35 to 0.75 microns in width and about 20 microns long. For a particular design and material, positioning pixel support arms 30 and 32 above the pixel in this manner increases the fill factor by about 20-30% as compared to a design where the arms are positioned in the same plane as, and on the sides of, the pixel. The pixel arrays of the invention have a fill factor of about 60-80%.

After completion of all pattern/etch steps, the polymer layers and photoresist are removed using plasma techniques or other methods that do not damage the patterned and fabricated pixel arrays. As used herein, and as would be understood by one skilled in the art, the polymer layer and the photoresist are first and second “sacrificial layers” that are removed from the completed sensor. The carrier substrate can also be considered a (third) sacrificial layer.

The as-fabricated individual die will comprise 25-micron pitch size pyroelectric pixel arrays such as 320×240 or 640×480 arrays.

### Example

1. A (001) textured LaNi0₃ thin film (first, top electrode 24) of about 600 A thick is deposited onto an oxide-coated Si substrate (carrier substrate 20) via sol-gel methods (ratio of La:Ni is about 1:1). The LaNi0₃ thin film deposition process comprises low temperature (˜240-420° C.) pyrolysis followed by high temperature (˜650-720° C.) crystallization in air using a rapid thermal annealer (˜1 minute, where temperature increases about 10-14° C./sec) at controlled dew point.

2. Once the LaNi0₃ film is processed, one or more thin films compositions (having a total thickness of 0.3 to 0.5 microns thick) of lead zirconium titanate (thermally sensitive layer 22) is deposited on the LaNi0₃ thin film via sol-gel methods, including low temperature pyrolysis (˜248-420° C.) followed by high temperature (˜650-720° C.) crystallization in air using a rapid thermal annealer (˜1 minute, where temperature increases about 10-14° C./sec).

3. A NiCr layer (second, bottom electrode 26) about 100-150 Å thick is then deposited on the lead zirconium titanate thin film(s) using RF sputtering in a low pressure Arambience (2.5 mTorr) under substrate bias conditions (0 to 30 W). A ˜30-50 nm thick layer of aluminum (Al) is then deposited under substrate bias conditions over the NiCr layer to facilitate poling.

4. For poling and testing, the exposed electrode (second electrode 26) on the carrier wafer is patterned into rectangular dice of about 9 mm×7 mm or 18 mm×14 mm in size following a conventional lithographic approach. Selective etch techniques are used to expose the LaNi0₃ (first electrode 24) on the carrier wafer to access the buried electrode (first electrode 24). The individual dice are poled at about 150° C., and aged for about 15 minutes at 150° C. prior to electrical and pyroelectric testing. The Al layer deposited over the NiCr layer is then dissolved a TMAH based developer like in CD-26 after poling.

5. The surface of the ROIC comprises a metallic layer (reflection layer 8) and two contact pads (10 and 12) for connecting to the pixels on the top wafer. The ROIC and the pyroelectric film stack are both coated with a 1-micron thick parylene-C layer using chemical vapor deposition methods. Both wafers are cleaned with solvents and oxygen ash techniques and coated with adhesion promoters.

6. The parylene-C coated ROIC and carrier wafer are bonded using conventional wafer bonding techniques at 150-250° C. and 240-250 psi. After bonding, the carrier wafer is removed using a combination of grinding and CMP and etching to expose LaNi0₃ as the top electrode (24) on the pixel.

7. The dice are patterned using lithographic techniques (Level-1) followed by chemical or reactive ion etch. The final pitch of pixels on each die will be 25 μm×25 μm in size, each pixel a square of about 23-micron size side separated by 2 microns from adjacent pixels. The pixel size and pitch can be variable depending upon the pixel design.

8. The patterned pyroelectric pixels are selectively etched (−4 or 5 microns square) at three corners (C1, C3 and C4) to expose the NiCr layer (second electrode 26) using a combination of lithographic techniques and RIE and/or wet chemical etch approaches (Level-2). This step will be followed by another lithographic pattern exposing two opposite corners (C1 and C3) on each individual pixel (Level-3).

9. After these steps a RIE technique will be used to etch vias through the sacrificial polymerlayer (16) to enable electrical contacts between individual pixels and individual ROIC pixel circuit.

10. Once the vias between pixel corners and ROIC contact pads are formed, a Level-4 pixel pattern exposing all four corners on the pixel is done using photolithography. A photoresist of ˜0.5 to 1 micron thick will be deposited in this step. This step will open vias between the second electrode 26 on the pixel and the top electrode 24 (LaNi0₃) at corner C4.

11. Following the above steps, a blanket layer of TiAl metal is deposited (about 0.05 microns thick) making electrical contacts with the ROIC contact pads. This metal layer will be patterned into pixel arms, as shown in FIG. 5, standing above the pixel.

12. The completed arrays will be released from the parylene-C using oxygen plasma processing.

Whereas particular embodiments of this invention have been described above for purposes of illustration, it will be evident to those skilled in the art that numerous variations of the details of the present invention may be made without departing from the invention as defined in the following claims.

What is claimed is:

1. A method of manufacturing a thermal sensing array comprising:
(a) providing a first wafer comprising an integrated circuit;
(b) providing a second wafer comprising a carrier substrate and a thermally sensitive layer sandwiched between a first electrode and a second electrode;
(c) applying a polymer to a surface of at least one of the first wafer and the second wafer;
(d) contacting the first wafer and the second wafer via the polymer for a period of time and at a temperature and pressure sufficient to create a bond;
(e) removing the carrier substrate; and
(f) patterning and etching the thermally sensitive layer, the first electrode, and the second electrode to create an array of pixels, wherein the first wafer and the second wafer are bonded without the need for fine alignment of the wafers.

2. The method of claim 1, wherein the polymer is parylene-C.

3. The method of claim 1, wherein the thermally sensitive layer is a pyroelectric material.

4. The method of claim 3, wherein the pyroelectric material is a thin film lead-based perovskite ferroelectric material.

5. The method of claim 4, wherein the lead-based perovskite ferroelectric material is lead zirconium titanate.

6. The method of claim 5, wherein the lead zirconium titanate is doped with manganese from 0.05 to 2 mol %.

7. The method of claim 3, wherein the pyroelectric material has its ferroelectric domains aligned in a desired direction either before or after step (d).

8. The method of claim 1, wherein the array of pixels is a 25 micron pitch allay.

9. The method of claim 1, further comprising, after step (f):
(g) depositing a photoresist over the top electrode;
(h) depositing an electrically conductive, thermally isolating material on the top of the photoresist; and
(i) patterning the material into pixel arms that are positioned above but separate from the pixel to provide thermal isolation of the pixel.

10. A method of manufacturing a thermal sensor array comprising:
(a) providing a wafer comprising an integrated circuit, a first sacrificial layer, a bottom electrode, a thermally sensitive layer, a top electrode and a second sacrificial layer on top of the top electrode;
(b) depositing a thermally insulating electrically conductive layer on top of the second sacrificial layer;
(c) patterning and etching the thermally insulating electrically conductive layer into support arms that provide electrical connectivity from the first electrode to the integrated circuit and from the second electrode to the integrated circuit; and
(d) removing the first and second sacrificial layers, wherein the support arms are positioned above but separate from the top electrode of each pixel in the array of pixels.

11. The method of claim 10, wherein:
the wafer of step (a) includes first and second wafers bonded together via the first sacrificial layer;
the first wafer comprises the integrated circuit;
the second wafer comprises the bottom electrode, the thermally sensitive layer, and the top electrode; and
following step (d), the support arms support the first and second wafers in spaced relation.

12. The method of claim 11, wherein each support arm is connected between a surface of the first wafer that faces the second wafer and a surface of the second wafer that faces away from the first wafer.

13. The method of claim 11, wherein ferroelectric domains of the thermally sensitive layer are aligned in a desired direction either before or after the first and second wafers are bonded together.

14. A pixel in a thermal sensor array, the pixel comprising:
an integrated circuit;
a bottom electrode associated with a first arm;
a thermally sensitive layer;
a top electrode associated with a second arm, the first and second arms providing electrical connectivity for the bottom and top electrodes, respectively, to the integrated circuit, each first and second arm positioned above but separated from the top electrode on the pixel, on the side incident to incoming thermal radiation.

15. The pixel of claim 14, wherein:
The integrated circuit comprises a first wafer;
the bottom electrode, the thermally sensitive layer, and the top electrode comprise a second wafer; and
the support arms support the first and second wafers in spaced relation.

16. The method of claim 15, wherein each support arm is connected between a surface of the first wafer that faces the second wafer and a surface of the second wafer that faces away from the first wafer.

17. An array of pixels, wherein each pixel comprises the pixel of claim 14.

18. The array of pixels of claim 17, wherein the array of pixels has a 25 micron pitch.

19. The array of pixels of claim 17, having a fill factor of greater than at least one of the following: 60 or 80%.

20. The array of pixels of claim 17, comprising either a 320×240 pixel array or a 640×480 pixel array.
